(19) United States
(12) Patent Application Publication
(10) Pub. No.: US 2009/0234603 A1
(43) Pub. Date: Sep. 17, 2009

(54) SYSTEM AND METHOD FOR ACCELERATING AN ELECTRICAL MEASUREMENT INSTRUMENT USING A GRAPHICAL PROCESSING UNIT

(75) Inventor: Karam Michael Noujeim, Sunnyvale, CA (US)

Correspondence Address: FLIESLER MEYER LLP, 650 CALIFORNIA STREET, 14TH FLOOR, SAN FRANCISCO, CA, 94108, US

(73) Assignee: Anritsu Company, Morgan Hill, CA (US)

(21) Appl. No.: 12/050,015

(22) Filed: Mar. 17, 2008

(51) Int. Cl. G01R 13/00

(52) U.S. Cl. 702/67; 702/57

(57) ABSTRACT

An electrical measurement instrument comprises an electrical measurement component, a computer to receive measurement data from the electrical measurement component, a central processing unit, one or more graphical processing units, a graphical processing unit programming interface to control the one or more graphical processing units, and a graphical processing unit-based mathematical library accessible to the graphical processing unit programming interface. The one or more graphical processing units perform processing of at least a portion of the measurement data.

### BACKGROUND

Vector network analyzers (VNAs), spectrum analyzers, oscilloscopes and other electrical measurement instruments represent some of the standard test tools for RF and microwave engineers. For example, the capability of VNAs to provide error-corrected amplitude and phase responses of active and passive components makes them invaluable in the research lab as well as on the production floor. While such instruments have been associated classically with racks of equipment in a testing lab, portable versions of them with reduced capability have been proliferating recently among field maintenance crews for on-site testing of antenna installations, cell sites, etc. This increasing interest has created a need to improve on the power efficiency and/or performance of portable measurement instruments so as to enhance their usability and reliability in the field.

### BRIEF DESCRIPTION OF THE DRAWINGS

FIG. 1 is a plot of historical floating-point performance of central processing units and graphical processing units as presented by NVIDIA Corp.

FIG. 2 is a block diagram of an electrical measurement instrument in accordance with the prior art.

FIG. 3 is a block diagram of an embodiment of an electrical measurement instrument in accordance with the present invention.

### DETAILED DESCRIPTION

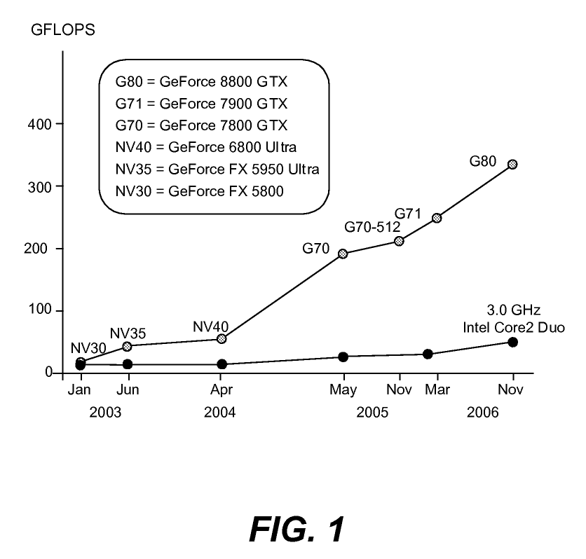

Graphical processing units (GPUs) were originally developed as dedicated graphics rendering devices for use as adjuncts to central processing units (CPUs). GPUs improve manipulation and display of computer graphics by performing calculations that accelerate CPU and memory-intensive tasks such as texture mapping, polygon rendering, and translating vertices into different coordinate systems. A highly parallel structure provides GPUs with floating-point performance that exceeds floating-point performance of current CPUs. FIG. 1 plots floating-point performance over time for GPUs manufactured by NVIDIA, Corp. and CPUs manufactured by Intel, Corp. As shown, the current generation NVIDIA G80 GPU, which has 128 processors and a memory bandwidth of 86.4 GB/s, can perform more than 320 billion floating-point operations per second (FLOPS), outperforming the current generation Intel Core2Duo.

Exceptional floating-point performance enables use of GPUs for executing a range of complex algorithms. As a result, GPUs are finding increased usage in non-graphics related applications including in computationally intensive areas such as numerical electromagnetics, fluid mechanics, fast Fourier transforms (FFT), and the solution to dense systems of linear equations. Enhanced performance in such applications can be attributed both to the massively multi-core nature of current GPUs and to a larger memory bandwidth relative to current CPUs. To facilitate such usage, NVIDIA, Corp. has made a programming interface available allowing programmers to harness the floating-point computational speed of GPUs manufactured by NVIDIA, Corp. In addition to the programming interface, two high-level libraries are included that can be used for performing FFTs as well as common vector and matrix operations. GPUs produced by NVIDIA and other manufacturers, such as ATI Technologies, a subsidiary of Advanced Micro Devices, Inc., may also be accessed for non-graphical or general purpose computations using a generic compiler, such as BrookGPU, a compiler and runtime implementation of the Brook stream programming language created by the Stanford University Graphics Lab.

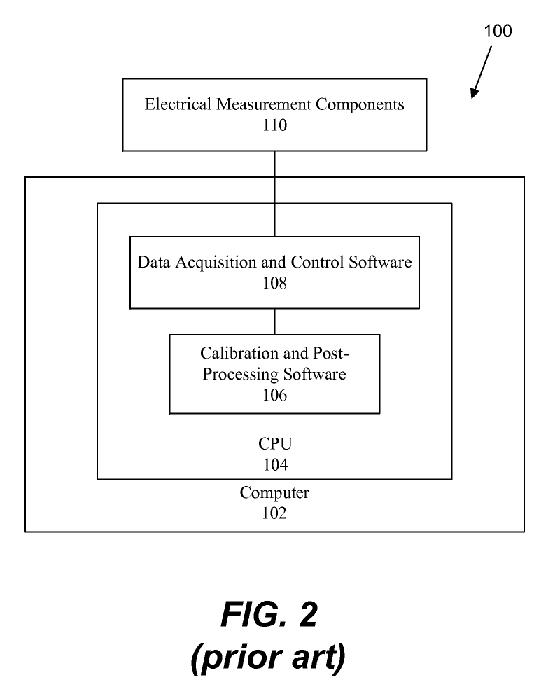

Electrical measurement instruments make use of mathematical operations such as FFTs, Hilbert transforms, windowing, convolution and deconvolution, and operations on vectors and matrices at various stages during instrument calibration, post-processing of data, or both. Referring to FIG. 2, a simplified block diagram of an electrical measurement instrument 100 in accordance with the prior art is shown. The electrical measurement instrument 100 can be a vector network analyzer (VNA), a spectrum analyzer, an oscilloscope, etc., and can include multiple different electrical measurement components 110 and different software algorithms for acquiring, controlling, and post-processing data, depending on the instrument type. For purposes of illustration, the electrical measurement instrument 100 will be described as a VNA. A VNA can comprise electrical measurement components 110 including a signal source for stimulus, a test set for signal separation, and a receiver for signal detection. A detected signal is sent to a computer 102 that can reside separate from the electrical measurement components (e.g., a stand-alone desktop) or local to the electrical measurement components (e.g., within an instrument housing). A CPU 104 of the computer 102 executes data acquisition and control software 108, and post-processes the reflection and transmission data to enable interpretation of the measurement results. The CPU 104 is also tasked to execute software to calibrate the VNA 100.

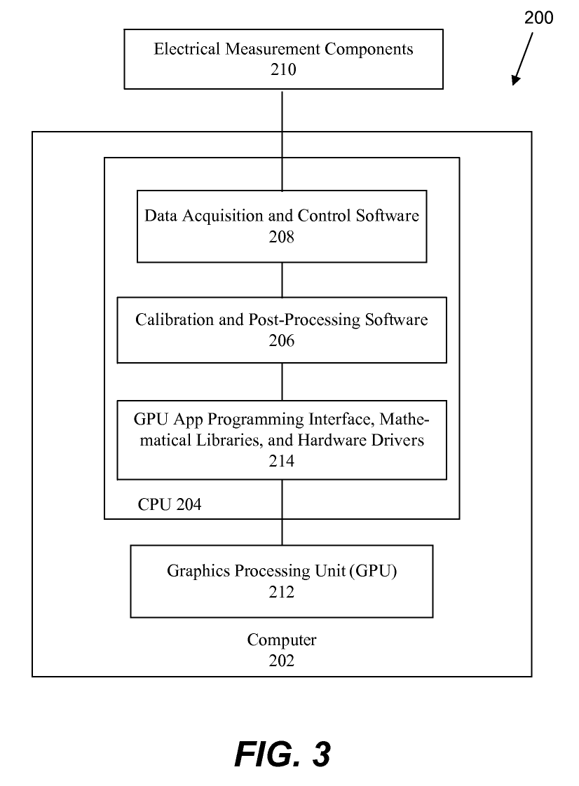

Referring to FIG. 3, a simplified block diagram of an embodiment of an electrical measurement instrument 200 in accordance with the present invention is shown. The embodiment makes use of a GPU to perform mathematical operations. GPUs are suited for processing data collected by electrical measurement instruments due in part to the vector nature of the data and the operations performed on the data. In situations where large data sets are collected and mathematical operations are to be performed on the large data sets, the floating-point computational parallelism of a GPU can be applied to maintain a desired speed and responsiveness of the measurement instrument. As above, the electrical measurement instrument 200 can include vector network analyzers (VNAs), spectrum analyzers, oscilloscopes, etc., each of which can include different electrical measurement components 210 and different software algorithms for acquiring, controlling, and post-processing data. For example, a VNA can comprise electrical measurement components 210 such as a signal source for stimulus, a test set for signal separation, and a receiver for signal detection. As above, a detected signal is sent to a computer 202 that can reside separate from the electrical measurement components (e.g., a stand-alone desktop) or local to the electrical measurement components (e.g., within an instrument housing). A CPU 204 of the computer 202 executes data acquisition and control software 208. The CPU 204 can manage data, optionally post-processing some of the data, while redirecting data to the GPU 212 for carrying out vector-based, computationally intensive tasks such as calibration and post-processing (e.g. FFTs, filtering, convolution, deconvolution, vector and matrix arithmetic, etc.). The CPU 204 then manages the results of the calculation performed by the GPU 212.

In addition to increased floating-point performance, GPUs exhibit improved power-consumption-to-performance ratio over CPUs, with the power consumption of a GPU being less than that of a CPU for achieving similar computational performance. Reduced power consumption can benefit battery-operated measurement instruments. By redirecting data for post-processing to the GPU 212, the electrical measurement instrument can reduce overall power consumption for a given set of results, prolonging battery life. It may be desired that the electrical measurement instrument divide measurement data between the CPU and the GPU for post-processing to reduce computation time. Measurement data processed using algorithms for which stream processing is advantageous may be prioritized to be processed on the GPU, for example. In a portable electrical measurement instrument powered by a battery, it may be desirable to balance processing speed with power consumption, managing the data to achieve a maximum level of performance while minifying power consumption to as low as possible. Embodiments of electrical measurement instruments in accordance with the present invention can benefit in unconsidered ways by incorporating a GPU accessible to a CPU. Such embodiments can improve performance of plug-in electrical measurement instruments, and/or reduce power consumption for portable, battery powered electrical measurement instruments.

The foregoing description of the present invention has been presented for purposes of illustration and description. It is not intended to be exhaustive or to limit the invention to the precise forms disclosed. Many modifications and variations will be apparent to practitioners skilled in this art. The embodiments were chosen and described in order to best explain the principles of the invention and its practical application, thereby enabling others skilled in the art to understand the invention for various embodiments and with various modifications as are suited to the particular use contemplated. It is intended that the scope of the invention be defined by the following claims and their equivalents.

1. An electrical measurement instrument comprising:
an electrical measurement component;
a computer to receive measurement data from the electrical measurement component;
a central processing unit;
one or more graphical processing units;
a graphical processing unit programming interface to control the one or more graphical processing units; and
a graphical processing unit-based mathematical library accessible to the graphical processing unit programming interface;
wherein the one or more graphical processing units perform processing of at least a portion of the measurement data.

2. The electrical measurement instrument of claim 1, wherein the electrical measurement instrument is portable.

3. The electrical measurement instrument of claim 2, wherein a first portion of the measurement data is processed by the central processing unit and a second portion of the measurement data is processed by the one or more graphical processing units.

4. The electrical measurement instrument of claim 3, wherein the first portion and second portion are assigned from the measurement data so that power consumption is minimized at a performance rate.

5. The electrical measurement instrument of claim 1, wherein the central processing unit is multi-core.

6. The electrical measurement instrument of claim 1, wherein the one or more graphical processing units is integrally formed with the central processing unit.

7. The electrical measurement instrument of claim 1, wherein the electrical measurement instrument is one of a vector network analyzer, a spectrum analyzer, and an oscilloscope.

8. The electrical measurement instrument of claim 7, wherein:
the electrical measurement instrument is a vector network analyzer; and
the electrical measurement component includes a signal source, a test set, and a receiver.

9. The electrical measurement instrument of claim 1, wherein the one or more graphical processing units are adapted to execute one or more of fast Fourier transforms, Hilbert transforms, windowing, convolution, deconvolution, vector operations and matrix operations.

10. The electrical measurement instrument of claim 1, wherein:
the computer includes software to acquire and control measurement data; and
the central processing unit is adapted to execute the software to acquire and control measurement data.

11. The electrical measurement instrument of claim 1, wherein:
the computer includes software to calibrate the measurement instrument and process measurement data; and
the central processing unit is adapted to distribute one or both of instruction and measurement data to the one or more graphical processing units and control data.

12. A method of processing measurements from an electrical measurement instrument including a computer having a central processing unit and a graphical processing unit comprising:
acquiring measurement data at the computer from an electric measurement component of the electrical measurement instrument;
controlling distribution of the measurement data to the graphical processing unit using the central processing unit;
processing at least a portion of the measurement data with the graphical processing unit;
returning results from the processing to the central processing unit; and
displaying the results.

13. The method of claim 12, wherein controlling distribution of the measurement data includes designating a first portion of the measurement data to be processed by the central processing unit and a second portion of the measurement data to be processed by the graphical processing unit.

14. The method of claim 13, wherein controlling distribution further comprises assigning measurement data to the first portion and the second portion to minimize power consumption at a performance rate.

15. The method of claim 12, wherein processing at least a portion of the measurement data with the graphical processing unit further includes executing one or more of fast Fourier transforms, Hilbert transforms, windowing, convolution, deconvolution, vector operations and matrix operations.

16. An electrical measurement instrument comprising:
an electrical measurement component;
a computer to receive measurement data from the electrical measurement component, the computer including:
a central processing unit;
a graphical processing unit;
a graphical processing unit programming interface to control the graphical processing unit; and
a graphical processing unit-based mathematical library accessible to the graphical processing unit programming interface;
wherein the central processing unit is adapted to distribute one or both of instructions and measurement data to the graphical processing unit using the graphical processing unit programming interface.

17. The electrical measurement instrument of claim 16, wherein:
the computer includes software to perform one or more of:
acquisition of measurement data;
control of measurement data;
calibration of the measurement instrument; and
processing of measurement data;
the central processing unit is adapted to execute the software to distribute the one or both of instructions and measurement data to the graphical processing unit.

18. The electrical measurement instrument of claim 16, wherein the electrical measurement instrument is one of a vector network analyzer, a spectrum analyzer, and an oscilloscope.

19. The electrical measurement instrument of claim 18, wherein:
the electrical measurement instrument is a vector network analyzer; and
the electrical measurement component includes a signal source, a test set, and a receiver.

20. The electrical measurement instrument of claim 16, wherein the graphical processing unit is adapted to execute one or more of fast Fourier transforms, Hilbert transforms, windowing, convolution, deconvolution, vector operations and matrix operations.
